(19) United States
(12) Patent Application Publication
(10) Pub. No.: US 2012/0212886 A1
(43) Pub. Date: Aug. 23, 2012

(54) ELECTRONIC DEVICE AND STAND

(75) Inventors: Ching-Hao Chou, Taipei City (TW); Yu-Yuan Lin, Taipei City (TW)

(73) Assignee: COMPAL ELECTRONICS, INC., Taipei City (TW)

(21) Appl. No.: 13/087,335

(22) Filed: Apr. 14, 2011

(30) Foreign Application Priority Data
Feb. 17, 2011 (TW) 100105266

(51) Int. Cl. H05K 7/00

(52) U.S. Cl. 361/679.01; 248/157

(57) ABSTRACT

An electronic device includes a body and a stand. The stand includes a base, a second stopping foot, a second sliding foot, and an elevator mechanism. The body is configured on the base, and a first stopping foot and a first sliding foot are configured on a bottom surface of the base. The elevator mechanism is configured on the base and interacts with the second stopping foot or the second sliding foot. High and low positions of the second stopping foot and the second sliding foot are exchanged by operation of the elevator mechanism, such that the first stopping foot, the first sliding foot, and the second stopping foot support the body on a platform, or the first stopping foot, the first sliding foot, and the second sliding foot support the body on the platform.

### CROSS-REFERENCE TO RELATED APPLICATION

This application claims the priority benefit of Taiwan application serial no. 100105266, filed Feb. 17, 2011. The entirety of the above-mentioned patent application is hereby incorporated by reference herein and made a part of this specification.

### BACKGROUND OF THE INVENTION

1. Field of the Invention

The invention relates to an electronic device and a stand thereof. More particularly, the invention relates to an electronic device having a display and a stand of the electronic device.

2. Description of Related Art

With the advancement of electronic industry, flat panel displays have been replacing conventional cathode ray tube (CRT) displays and have become mainstream display products. Among the flat panel display technologies, the liquid crystal display (LCD) technology is the most mature and prevalent. Specifically, the LCD technology is applicable to an LCD monitor, an LCD TV, an all-in-one PC, and other electronic devices.

In most cases, the electronic devices including the LCD monitor, the LCD TV, or the all-in-one PC can be configured on stands that support the electronic devices, such that users can easily use the electronic devices. A stopping foot can be configured on the bottom surface of the stand, so as to increase friction between the stand and the tabletop. Although said configuration can effectively prevent the stand from sliding on the tabletop unexpectedly, the configuration also brings about difficulties in rotating the stand in order to adjust the position of the stand.

### SUMMARY OF THE INVENTION

The invention is directed to an electronic device that has a stand. The stand has exchangeable stopping and sliding feet, so as to achieve both a non-slip function and a rotation function.

The invention is directed to a stand that has exchangeable stopping and sliding feet, so as to achieve both a non-slip function and a rotation function.

In an embodiment of the invention, an electronic device that includes a body and a stand is provided. The stand includes a base, a second stopping foot, a second sliding foot, and an elevator mechanism. The body is configured on the base, and a first stopping foot and a first sliding foot are configured on a bottom surface of the base. The elevator mechanism is configured on the base and interacts with the second stopping foot or the second sliding foot. High and low positions of the second stopping foot and the second sliding foot can be exchanged by operation of the elevator mechanism, such that the first stopping foot, the first sliding foot, and the second stopping foot support the body on a platform, or the first stopping foot, the first sliding foot, and the second sliding foot support the body on the platform.

In an embodiment of the invention, a stand adapted to an electronic device is provided. The electronic device includes a body. The stand includes a base, a second stopping foot, a second sliding foot, and an elevator mechanism. The body is configured on the base, and a first stopping foot and a first sliding foot are configured on a bottom surface of the base. The elevator mechanism is configured on the base and interacts with the second stopping foot or the second sliding foot. High and low positions of the second stopping foot and the second sliding foot can be exchanged by operation of the elevator mechanism, such that the first stopping foot, the first sliding foot, and the second stopping foot support the body on a platform, or the first stopping foot, the first sliding foot, and the second sliding foot support the body on the platform.

Based on the foregoing, in the stand as described in the embodiments of the invention, the operation of the elevator mechanism leads to relative elevation and descent of the second stopping foot and the second sliding foot, such that the second stopping foot is in contact with the platform when the second sliding foot is suspended in midair, or the second sliding foot is in contact with the platform when the second stopping foot is suspended in midair. Specifically, when the second stopping foot is in contact with the platform, and the second sliding foot is suspended in midair, the first stopping foot, the first sliding foot, and the second stopping foot support the body on the platform, so as to prevent the electronic device from unexpectedly sliding or rotating on the platform. By contrast, when the second sliding foot is in contact with the platform, and the second stopping foot is suspended in midair, the first stopping foot, the first sliding foot, and the second sliding foot support the body on the platform, so as to allow the electronic device to rotate on the platform around the first stopping foot. Through the exchanged positions of the second stopping foot and the second sliding foot, the stand can be equipped with both the non-slip function and the rotation function, i.e., the stand described in the embodiments of the invention can be extensively applied.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a three-dimensional view illustrating an electronic device according to an embodiment of the invention.

FIG. 2 is a three-dimensional view illustrating the electronic device depicted in FIG. 1 from another viewing angle.

FIG. 3 is a partial side view illustrating the electronic device depicted in FIG. 1.

FIG. 4 is a schematic view illustrating the relative elevation and descent of the second stopping foot and the second sliding foot depicted in FIG. 3.

FIG. 5 is a top view illustrating the stand depicted in FIG. 1.

FIG. 6A and FIG. 6B are schematic views illustrating the rotation of the stand depicted in FIG. 5.

FIG. 7 is a three-dimensional view illustrating the stand depicted in FIG. 1.

FIG. 8 is an explosive view illustrating the stand depicted in FIG. 7.

FIG. 9 is a partial three-dimensional view illustrating the stand depicted in FIG. 7.

FIG. 10 is a schematic view illustrating the operation of the elevator mechanism depicted in FIG. 9.

FIG. 11 is a three-dimensional view illustrating the rotation member depicted in FIG. 8.

FIG. 12 is an explosive view illustrating the rotation member depicted in FIG. 11.

### DESCRIPTION OF EMBODIMENTS

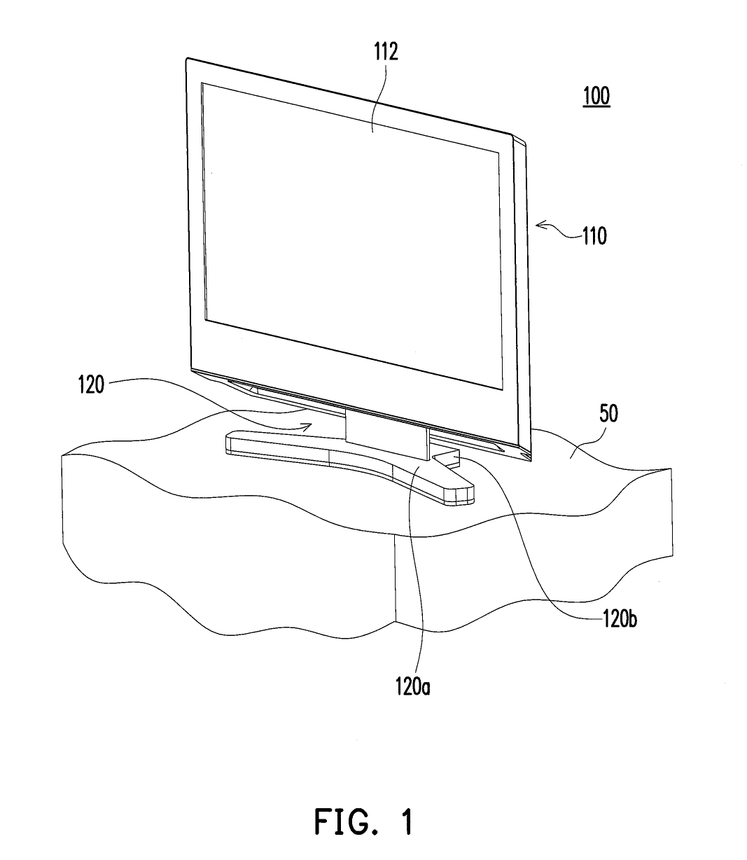

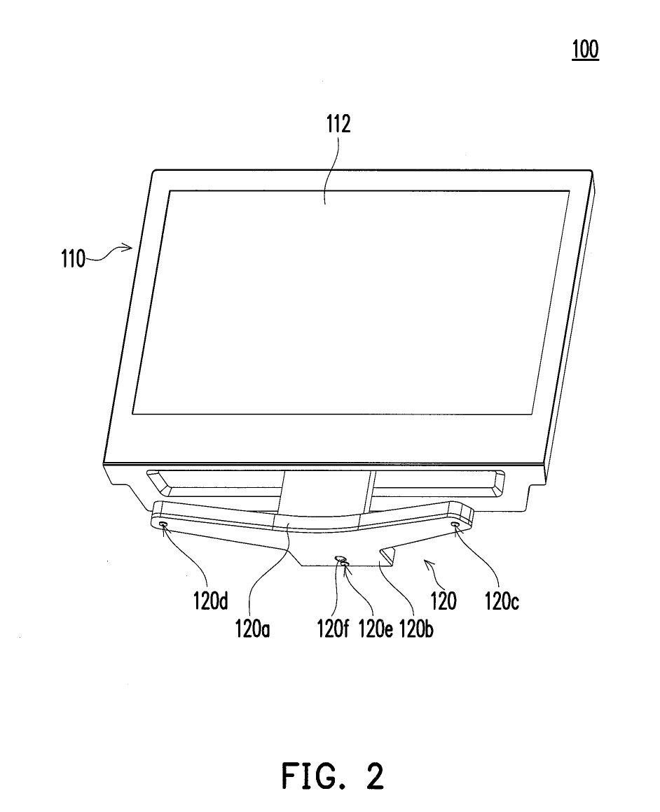

FIG. 1 is a three-dimensional view illustrating an electronic device according to an embodiment of the invention. FIG. 2 is a three-dimensional view illustrating the electronic device depicted in FIG. 1 from another viewing angle. With reference to FIG. 1 and FIG. 2, the electronic device 100 of this embodiment includes a body 110 and a stand 120. The body 110 has a display 112. The stand 120 includes a base 120a and an elevator mechanism 120b. The body 110 is configured on the base 120a, such that the body 110 is supported on a platform 50 by the stand 120. Thereby, a user can easily use the electronic device 100. A first stopping foot 120c and a first sliding foot 120d are configured on a bottom surface of the base 120a. The stand 120 further includes a second stopping foot 120e and a second sliding foot 120f. The elevator mechanism 120b is configured on the base 120a and interacts with the second stopping foot 120e or the second sliding foot 120f.

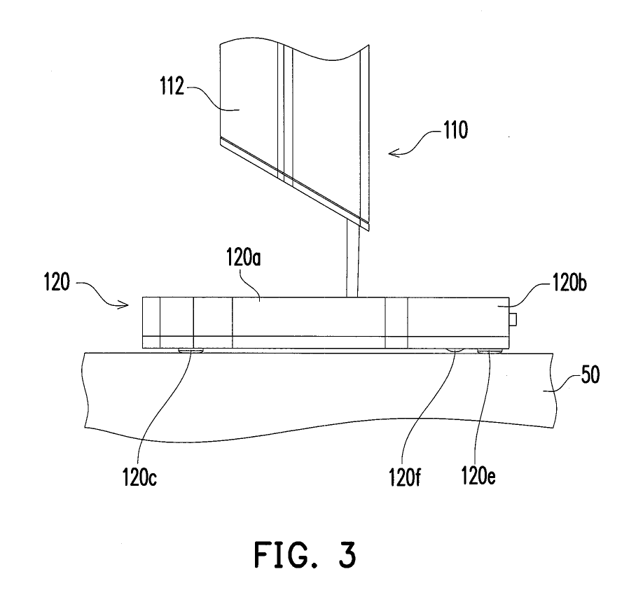

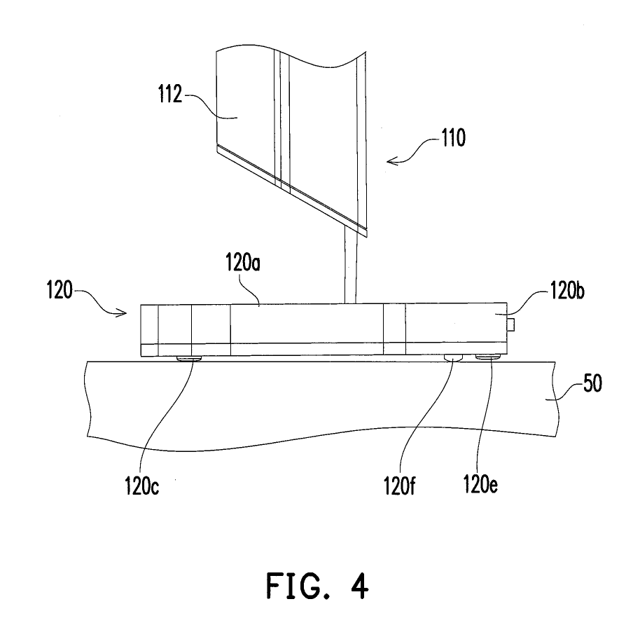

FIG. 3 is a partial side view illustrating the electronic device depicted in FIG. 1. FIG. 4 is a schematic view illustrating the relative elevation and descent of the second stopping foot and the second sliding foot depicted in FIG. 3, and thus the high and low positions of the second stopping foot and the second sliding foot can be exchanged. The second stopping foot 120e and the second sliding foot 120f can be relatively elevated and descended together with the operation of the elevator mechanism 120b, such that the second stopping foot 120e is in contact with the platform 50 when the second sliding foot 120f is suspended in midair (shown in FIG. 3), or the second sliding foot 120f is in contact with the platform 50 when the second stopping foot 120e is suspended in midair (shown in FIG. 4).

Specifically, when the second stopping foot 120e is in contact with the platform 50, and the second sliding foot 120f is suspended in midair, the first stopping foot 120c, the first sliding foot 120d, and the second stopping foot 120e support the display 112 on the platform 50, so as to prevent the electronic device 100 from unexpectedly sliding or rotating on the platform 50. By contrast, when the second sliding foot 120f is in contact with the platform 50, and the second stopping foot 120e is suspended in midair, the first stopping foot 120c, the first sliding foot 120d, and the second sliding foot 120f support the body 110 on the platform 50, so as to allow the electronic device 100 to rotate on the platform 50 around the first stopping foot 120c. Through the exchanged positions of the second stopping foot 120e and the second sliding foot 120f, the stand 120 can be equipped with both the non-slip function and the rotation function, i.e., the stand 120 described in the embodiments of the invention can be extensively applied.

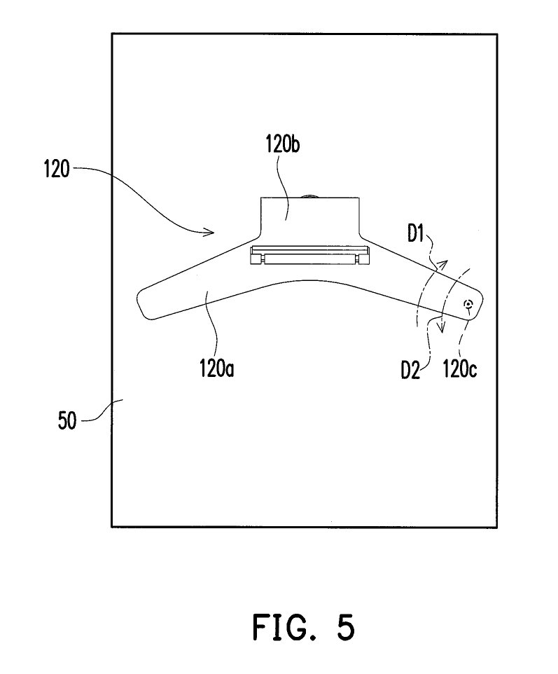

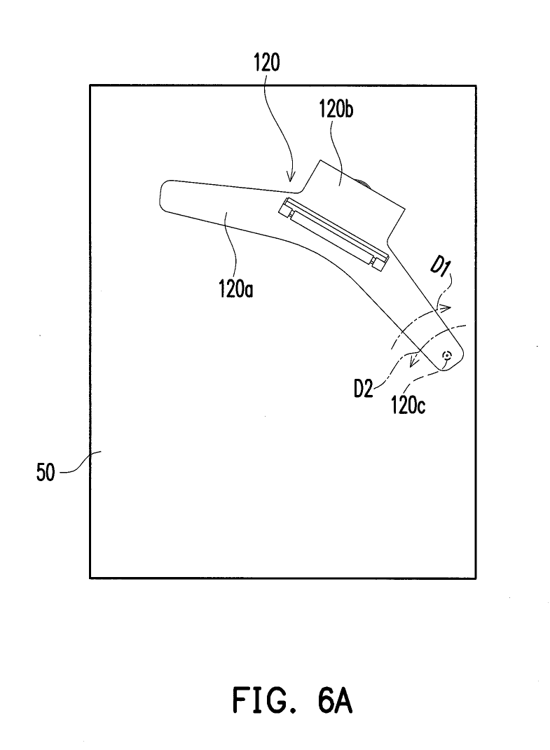

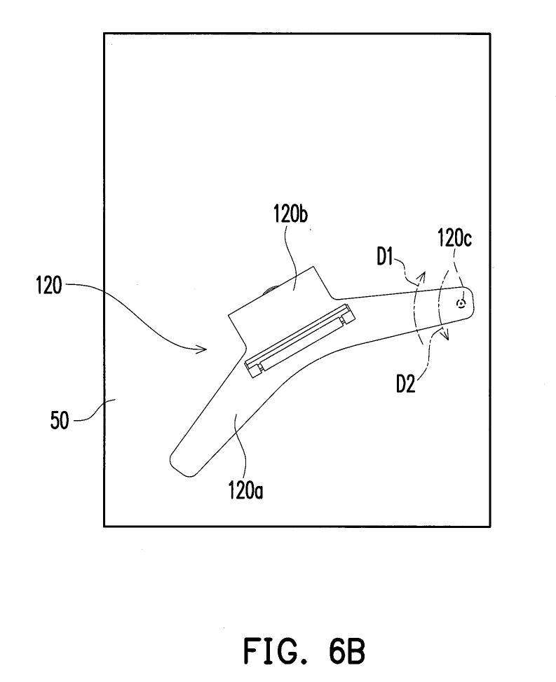

FIG. 5 is a top view illustrating the stand depicted in FIG. 1. FIG. 6A and FIG. 6B are schematic views illustrating the rotation of the stand depicted in FIG. 5. With reference to FIG. 4, FIG. 5, FIG. 6A, and FIG. 6B, for instance, when the second sliding foot 120f is in contact with the platform 50, and the second stopping foot 120e is suspended in midair, as shown in FIG. 4, the stand 120 can be rotated around the first stopping foot 120c along a rotation direction D1 shown in FIG. 5, and the rotated stand 120 is depicted in FIG. 6A. Alternatively, the stand 120 can be rotated around the first stopping foot 120c along a rotation direction D2 shown in FIG. 5, and the rotated stand 120 is depicted in FIG. 6B. In other words, the first stopping foot 120c serves as a pivot point during rotation.

In this embodiment, the first stopping foot 120c, the first sliding foot 120d, and the second stopping foot 120e are not substantially located on the same straight line, such that the first stopping foot 120c, the first sliding foot 120d, and the second stopping foot 120e can stably support the body 110 on the platform 50. Besides, the first stopping foot 120c, the first sliding foot 120d, and the second sliding foot 120f are not substantially located on the same straight line, such that the first stopping foot 120c, the first sliding foot 120d, and the second sliding foot 120f can stably support the body 110 on the platform 50.

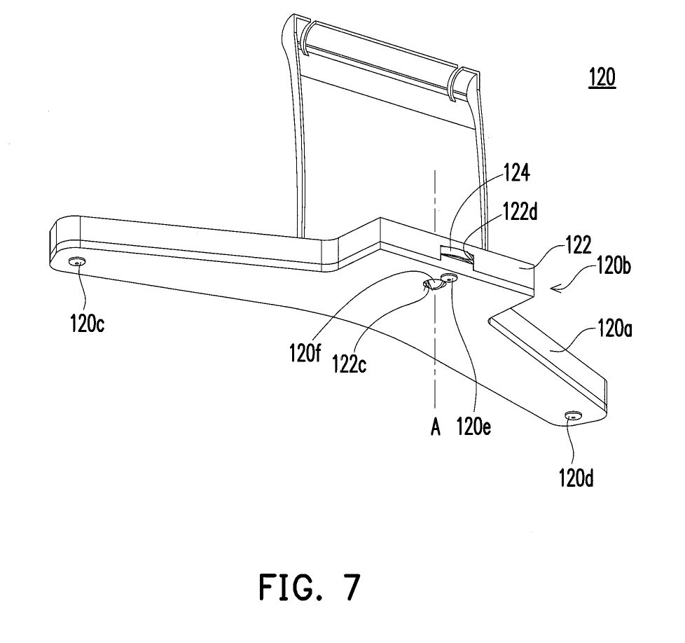

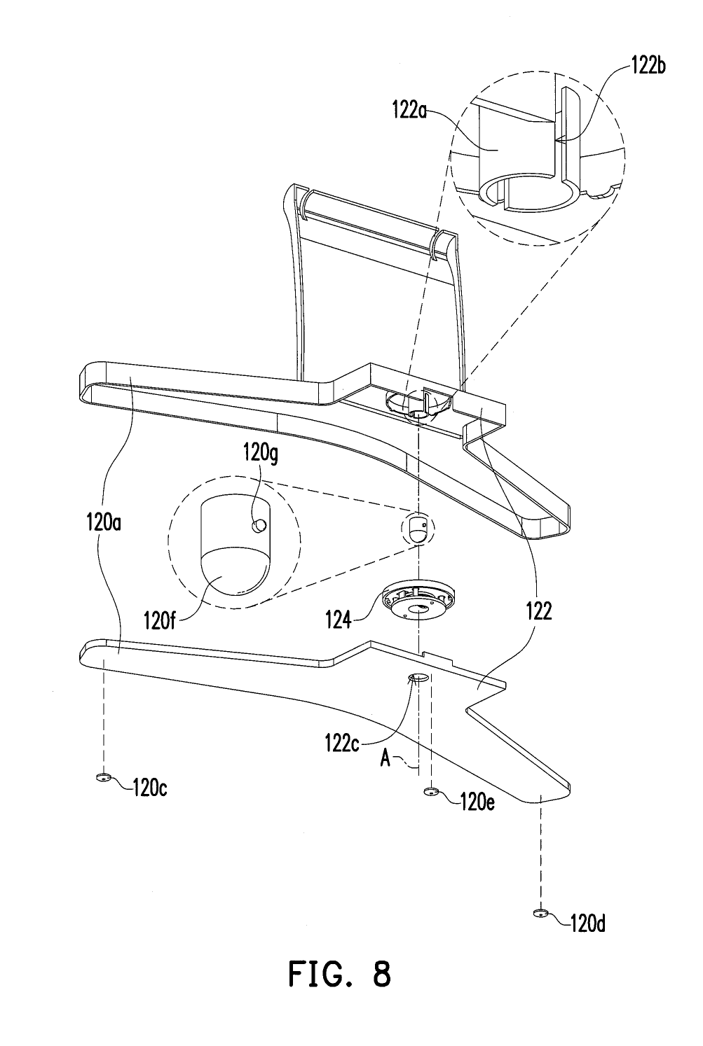

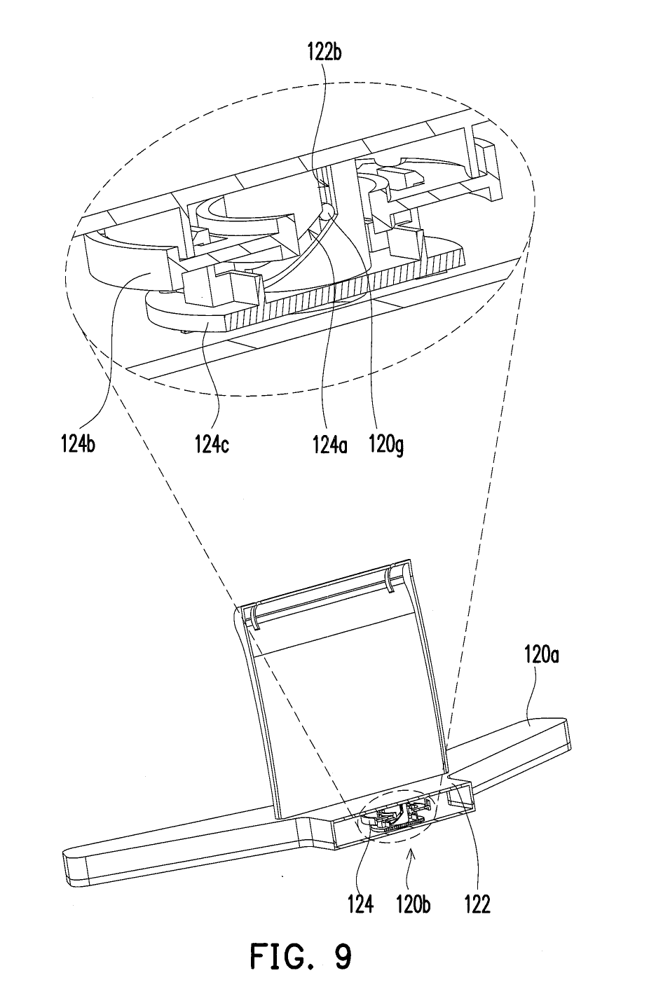

FIG. 7 is a three-dimensional view illustrating the stand depicted in FIG. 1. FIG. 8 is an explosive view illustrating the stand depicted in FIG. 7. FIG. 9 is a partial three-dimensional view illustrating the stand depicted in FIG. 7. With reference to FIG. 7 to FIG. 9, particularly, the elevator mechanism 120b of this embodiment includes a casing 122 and a rotation member 124. The casing 122 is connected to the base 120a and has a sliding portion 122a. The second stopping foot 120e is configured on a bottom surface of the casing 122. The second sliding foot 120f is slidably configured in the sliding portion 122a along an axis A and has a protrusion 120g. The sliding portion 122a has a first slot 122b. An extension direction of the first slot 122b is parallel to the axis A, and the protrusion 120g passes through the first slot 122b. The rotation member 124 is pivotally configured at the bottom of the casing 122 along the axis A and has a second slot 124a. An extension direction of the second slot 124a tilts toward the axis A, and the protrusion 120g passes through the second slot 124a.

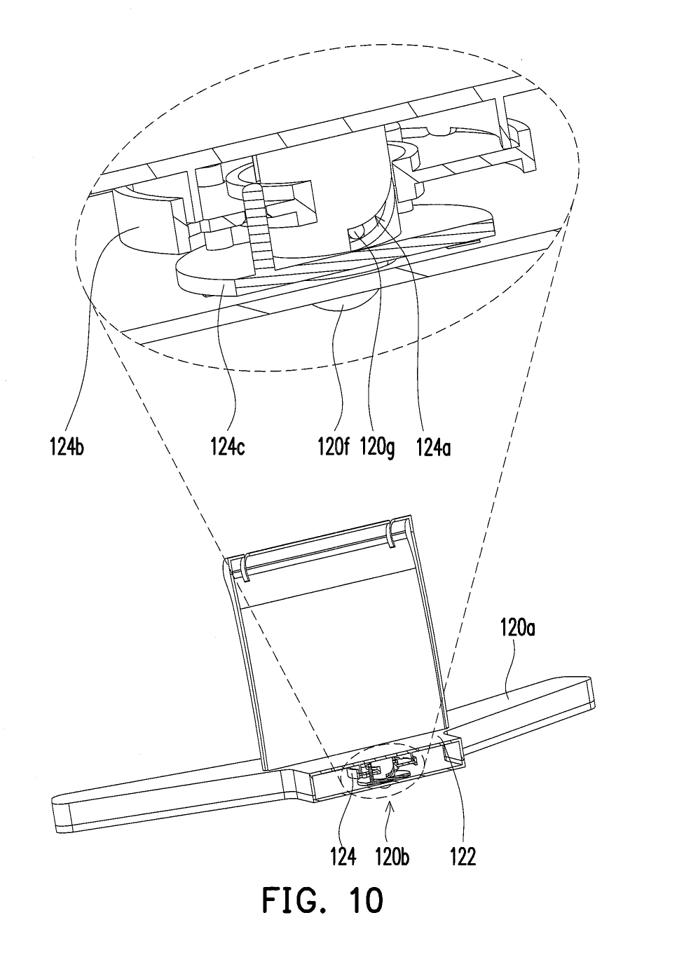

Under said arrangement, the protrusion 120g is slidably configured in the first slot 122b that is parallel to the axis A. Therefore, the second sliding foot 120f is restrained to slide relative to the casing 122 along the axis A. FIG. 10 is a schematic view illustrating the operation of the elevator mechanism depicted in FIG. 9. When the rotation member 124 shown in FIG. 9 rotates relative to the casing 122 and is in the state shown in FIG. 10, the rotation member 124 moves the protrusion 120g along the axis A through the second slot 124a, and the protrusion 120g moves from the position shown in FIG. 9 to the position shown in FIG. 10. Thereby, the second sliding foot 120f descends relative to the second stopping foot 120e. As a result, the high and low positions of the second sliding foot 120f and the second stopping foot 120e are exchanged.

As indicated in FIG. 7 and FIG. 8, in this embodiment, the bottom surface of the casing 122 has an opening 122c, and the second sliding foot 120f is suitable for sliding along the axis A and protruding from the opening 122c. Thereby, the second stopping foot 120e is moved away from the platform 50, as shown in FIG. 4. In addition, the casing 122 of this embodiment has an opening 122d that exposes a portion of the rotation member 124, such that a user can manually rotate the rotation member 124 with ease.

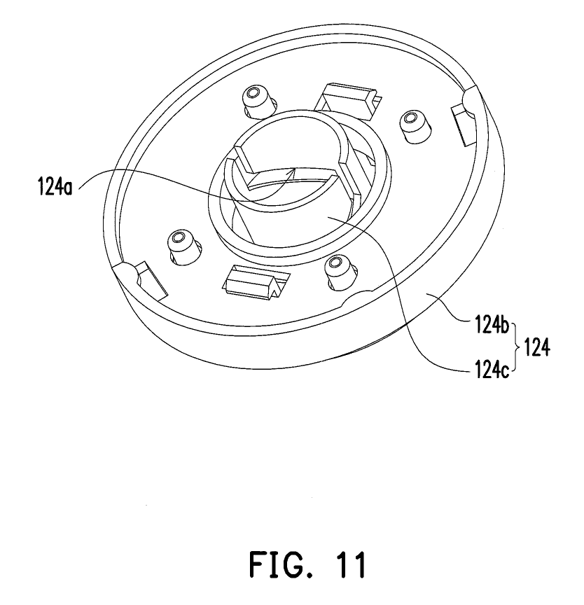

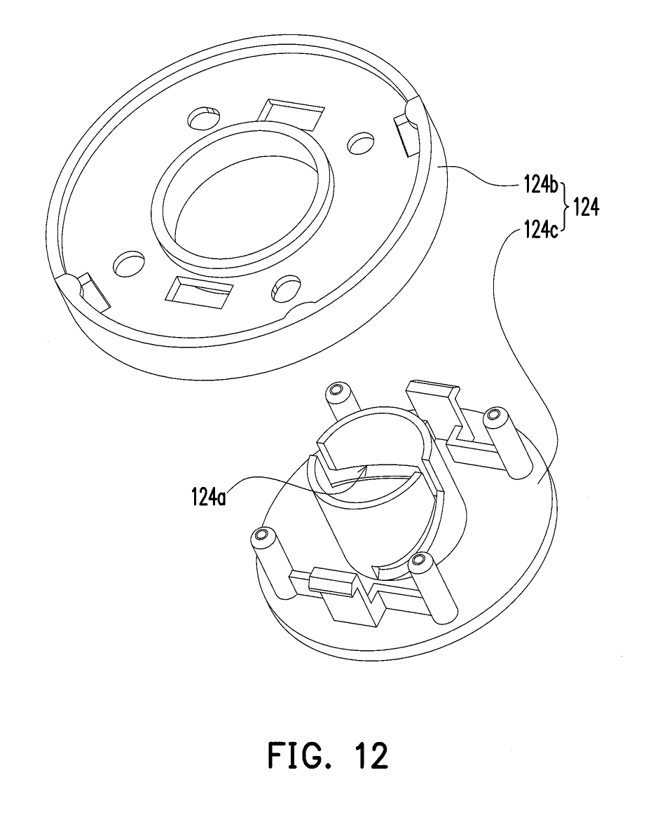

FIG. 11 is a three-dimensional view illustrating the rotation member depicted in FIG. 8. FIG. 12 is an explosive view illustrating the rotation member depicted in FIG. 11. With reference to FIG. 11 and FIG. 12, the rotation member 124 of this embodiment includes a first component 124b and a second component 124c that are assembled together. The first component 124b is pivotally connected to the casing 122, and the second slot 124a is formed in the second component 124c. However, the type of the rotation member 124 is not limited in the invention. According to other embodiments of the invention, the rotation member 124 can be an individual element that is pivotally connected to the casing 122 and has the second slot 124a.

According to this embodiment, a material of the first stopping foot 120c and a material of the second stopping foot 120e are rubber, for instance, and a material of the first sliding foot 120d and a material of the second sliding foot 120f are polyoxymethylene (POM, also known as plastic steel), for instance. Nevertheless, the invention is not limited thereto. In other embodiments of the invention, the first stopping foot 120c and the second stopping foot 120e can be made of other appropriate materials for achieving the non-slip function, and the first sliding foot 120d and the second sliding foot 120f can also be made of other appropriate materials for achieving the sliding function.

According to other embodiments of the invention, the second stopping foot 120e can be replaced by a foot with sliding properties, and the second sliding foot 120f can be replaced by a foot with non-slip properties. Under this arrangement, the positions of the stopping and sliding feet can also be exchanged by the operation of the elevator mechanism 120b as described above, such that the stand 120 can accomplish both the non-slip effect and the rotation effect.

To sum up, in the stand described in the embodiments of the invention, the operation of the elevator mechanism leads to relative elevation and descent of the second stopping foot and the second sliding foot, such that the second stopping foot is in contact with the platform when the second sliding foot is suspended in midair, or the second sliding foot is in contact with the platform when the second stopping foot is suspended in midair. Specifically, when the second stopping foot is in contact with the platform, and the second sliding foot is suspended in midair, the first stopping foot, the first sliding foot, and the second stopping foot support the body on the platform, so as to prevent the electronic device from unexpectedly sliding or rotating on the platform. By contrast, when the second sliding foot is in contact with the platform, and the second stopping foot is suspended in midair, the first stopping foot, the first sliding foot, and the second sliding foot support the body on the platform, so as to allow the electronic device to rotate on the platform around the first stopping foot. Through the exchanged positions of the second stopping foot and the second sliding foot, the stand can be equipped with both the non-slip function and the rotation function, i.e., the stand described in the embodiments of the invention can be extensively applied.

Although the invention has been described with reference to the above embodiments, it will be apparent to one of the ordinary skill in the art that modifications to the described embodiments may be made without departing from the spirit of the invention. Accordingly, the scope of the invention will be defined by the attached claims rather than by the above detailed descriptions.

What is claimed is:

1. An electronic device comprising:
a body; and
a stand comprising:
a base, the body being configured on the base, a first stopping foot and a first sliding foot being configured on a bottom surface of the base;
a second stopping foot;
a second sliding foot; and
an elevator mechanism configured on the base and interacting with the second stopping foot or the second sliding foot, wherein high and low positions of the second stopping foot and the second sliding foot are exchanged by operation of the elevator mechanism, such that the first stopping foot, the first sliding foot, and the second stopping foot support the body on a platform, or the first stopping foot, the first sliding foot, and the second sliding foot support the body on the platform.

2. The electronic device as claimed in claim 1, wherein a material of the first stopping foot and a material of the second stopping foot are rubber.

3. The electronic device as claimed in claim 1, wherein a material of the first sliding foot and a material of the second sliding foot are polyoxymethylene.

4. The electronic device as claimed in claim 1, wherein the first stopping foot, the first sliding foot, and the second stopping foot are not substantially located on a same straight line.

5. The electronic device as claimed in claim 1, wherein the first stopping foot, the first sliding foot, and the second sliding foot are not substantially located on a same straight line.

6. The electronic device as claimed in claim 1, wherein the elevator mechanism comprises:
a casing connected to the base and having a sliding portion, wherein the second stopping foot is configured on a bottom surface of the casing, the second sliding foot is slidably configured in the sliding portion along an axis and has a protrusion, the sliding portion has a first slot, an extension direction of the first slot is parallel to the axis, and the protrusion passes through the first slot; and
a rotation member pivotally configured at a bottom of the casing along the axis and having a second slot, an extension direction of the second slot tilting toward the axis, the protrusion passing through the second slot, the rotation member being suitable for rotating relative to the casing and moving the protrusion along the first slot and the second slot, such that the second sliding foot slides along the axis and is elevated or descended relative to the second stopping foot, and that the high and low positions of the second sliding foot and the second stopping foot are exchanged.

7. The electronic device as claimed in claim 6, wherein the bottom surface of the casing has an opening, and the second sliding foot is suitable for sliding along the axis and protruding from the opening.

8. The electronic device as claimed in claim 1, wherein the elevator mechanism comprises:
a casing connected to the base and having a sliding portion, wherein the second sliding foot is configured on a bottom surface of the casing, the second stopping foot is slidably configured in the sliding portion along an axis and has a protrusion, the sliding portion has a first slot, an extension direction of the first slot is parallel to the axis, and the protrusion passes through the first slot; and
a rotation member pivotally configured at a bottom of the casing along the axis and having a second slot, an extension direction of the second slot tilting toward the axis, the protrusion passing through the second slot, the rotation member being suitable for rotating relative to the casing and moving the protrusion along the first slot and the second slot, such that the second stopping foot moves along the axis and is elevated or descended relative to the second sliding foot, and that the high and low positions of the second stopping foot and the second sliding foot are exchanged.

9. The electronic device as claimed in claim 8, wherein the bottom surface of the casing has an opening, and the second stopping foot is suitable for moving along the axis and protruding from the opening.

10. The electronic device as claimed in claim 1, wherein when the first stopping foot, the first sliding foot, and the second sliding foot support the body on the platform, the electronic device is suitable for rotating on the platform around the first stopping foot.

11. The electronic device as claimed in claim 1, wherein the body has a display.

12. A stand adapted to an electronic device, the electronic device comprising a body, the stand comprising:
a base, the body being configured on the base, a first stopping foot and a first sliding foot being configured on a bottom surface of the base;
a second stopping foot;
a second sliding foot; and
an elevator mechanism configured on the base and interacting with the second stopping foot or the second sliding foot, wherein high and low positions of the second stopping foot and the second sliding foot are exchanged by operation of the elevator mechanism, such that the first stopping foot, the first sliding foot, and the second stopping foot support the body on a platform, or the first stopping foot, the first sliding foot, and the second sliding foot support the body on the platform.

13. The stand as claimed in claim 12, wherein a material of the first stopping foot and a material of the second stopping foot are rubber.

14. The stand as claimed in claim 12, wherein a material of the first sliding foot and a material of the second sliding foot are polyoxymethylene.

15. The stand as claimed in claim 12, wherein the first stopping foot, the first sliding foot, and the second stopping foot are not substantially located on a same straight line.

16. The stand as claimed in claim 12, wherein the first stopping foot, the first sliding foot, and the second sliding foot are not substantially located on a same straight line.

17. The stand as claimed in claim 12, wherein the elevator mechanism comprises:
a casing connected to the base and having a sliding portion, wherein the second stopping foot is configured on a bottom surface of the casing, the second sliding foot is slidably configured in the sliding portion along an axis and has a protrusion, the sliding portion has a first slot, an extension direction of the first slot is parallel to the axis, and the protrusion passes through the first slot; and
a rotation member pivotally configured at a bottom of the casing along the axis and having a second slot, an extension direction of the second slot tilting toward the axis, the protrusion passing through the second slot, the rotation member being suitable for rotating relative to the casing and moving the protrusion along the first slot and the second slot, such that the second sliding foot slides along the axis and is elevated or descended relative to the second stopping foot, and that the high and low positions of the second sliding foot and the second stopping foot are exchanged.

18. The stand as claimed in claim 17, wherein the bottom surface of the casing has an opening, and the second sliding foot is suitable for sliding along the axis and protruding from the opening.

19. The stand as claimed in claim 12, wherein the elevator mechanism comprises:
a casing connected to the base and having a sliding portion, wherein the second sliding foot is configured on a bottom surface of the casing, the second stopping foot is slidably configured in the sliding portion along an axis and has a protrusion, the sliding portion has a first slot, an extension direction of the first slot is parallel to the axis, and the protrusion passes through the first slot; and
a rotation member pivotally configured at a bottom of the casing along the axis and having a second slot, an extension direction of the second slot tilting toward the axis, the protrusion passing through the second slot, the rotation member being suitable for rotating relative to the casing and moving the protrusion along the first slot and the second slot, such that the second stopping foot moves along the axis and is elevated or descended relative to the second sliding foot, and that the high and low positions of the second stopping foot and the second sliding foot are exchanged.

20. The stand as claimed in claim 19, wherein the bottom surface of the casing has an opening, and the second stopping foot is suitable for moving along the axis and protruding from the opening.

21. The stand as claimed in claim 12, wherein when the first stopping foot, the first sliding foot, and the second sliding foot support the body on the platform, the electronic device is suitable for rotating on the platform around the first stopping foot.
